(19) United States
(12) Patent Application Publication
(10) Pub. No.: US 2007/0222087 A1
(43) Pub. Date: Sep. 27, 2007

(54) SEMICONDUCTOR DEVICE WITH SOLDERABLE LOOP CONTACTS

(76) Inventors: Sangdo Lee, Suzhou (CN); Margie T. Rios, Lapulapu City (PH)

Correspondence Address: HISCOCK & BARCLAY, LLP, 2000 HSBC PLAZA, 100 Chestnut Street, ROCHESTER, NY, 14604-2404, US

(21) Appl. No.: 11/690,900

(22) Filed: Mar. 26, 2007

Related U.S. Application Data
(60) Provisional application No. 60/786,139, filed on Mar. 27, 2006.

(51) Int. Cl. H01L 23/52

(52) U.S. Cl. 257/784

(57) ABSTRACT

A method of easily manufacturing reliable solder contacts on semiconductor dies are made in the shape of a loop made from metal wires or ribbons that may be coated with other solderable metals. The loops can be in multi loop form, single loop forms or both on the semiconductor die. The loop contacts may be formed on the die using thermosonic or ultrasonic bonding. The die may also be packaged with encapsulating material leaving the die exposed through the encapsulating material as a solder-ready contact for the device.

### CROSS-REFERENCE TO RELATED APPLICATIONS

This application claims the benefit of U.S. Provisional Patent Application Ser. No. 60/786,139, filed Mar. 27, 2006, which is hereby incorporated by reference.

### FIELD OF THE INVENTION

This invention relates to a semiconductor device, specifically, a semiconductor device having loop contacts as solderable surfaces, providing for a less expensive and more efficient method of manufacturing solderable contacts on a semiconductor die.

### BACKGROUND OF THE INVENTION

The device of the present invention is a semiconductor device having a more efficient and less expensive method of manufacturing solderable contacts. The device requires less time for manufacturing because of its simple design.

Semiconductor devices that have solderable contacts such as bumps, solder bumps, or stud bumps formed on the semiconductor die are well known in the art. Devices with bumps formed on the device require extra procedures compared to the method of manufacturing devices of the present invention. Devices having bumps on the die require copper wires for forming the bumps on the die, flux encapsulating, forming the solder bumps, and lastly a reflow process.

The problems associated with these prior devices are that the manufacturing process is detailed. Also the solder contacts were not reliable because bumps are susceptible to cracking after board mounting.

It is desired to have more efficient and less complicated method of manufacturing a semiconductor device.

It is desired to have reliable contacts for soldering or attaching a semiconductor device to board mountings.

### SUMMARY OF THE INVENTION

In an embodiment of the invention a semiconductor device comprises a semiconductor die, a die attach pad attached to the drain region of the die, and solderable loop contacts bonded to the source and gate region of the die. The loop contacts are made from a solderable metal wire or ribbon, that can optionally be coated with another solderable metal. The methods of bonding the loop contacts to the die are either thermosonic bonding or ultrasonic bonding.

More particularly, the invention includes in its first embodiment a semiconductor device with loop contacts thermosonically bonded in single contacts, multi contacts, or both. The loop contacts are made from a solderable metal wire such as gold or copper, and the wire may further be coated by copper, nickel palladium, or platinum. The device may be packaged with encapsulating material, and attached to an application board using solder.

In a second embodiment, the bonding site is on stud bumps formed on the die. Bonding the loop contacts to the stud bumps, as opposed to the die, directly, prevents damage to the semiconductor die due to the heat required for the thermosonic bonding process. Once the loop contacts are formed, the device may be encapsulated using encapsulating material leaving the loop contacts exposed through the encapsulating material. The metal wires are copper or gold and may be further coated with copper, nickel, palladium, or platinum.

In a third embodiment, the device has loop contacts made from either a metal wire or ribbon. The wire or ribbon is made from a solderable metal such as copper, aluminum, or gold, and may be optionally coated with copper, nickel, palladium, and platinum. The wire or ribbon is bonded to the die by ultrasonic bonding techniques directly to the die. Again, the die may be optionally packaged using encapsulating material.

An advantage of the present invention is that the device allows for an efficient manufacturing process. It eliminates the need for photoresist dispensing, development, metal plating, forming bumps and reflow. After the die is attached to the die attach pad, the wire or ribbon is bonded directly to the die without the need for intermediary steps. As mentioned in detail below, the thermosonic bonding process requires insertion of the wire into a bonding tool, which is heated and then attached to the die. Thereafter, other bonds can be made by attaching the wire in the bonding tool to the die, and creating a wedge bond to the die or bonding surface. No further steps are required, at least as concerned with the loop contact manufacturing process, such as a reflow process in the manufacturing process of forming stud or solder bumps.

Another advantage of the present invention is that the loop contacts are durable and reliable solder contacts. The prior devices, such as devices with stud balls or bumps, are susceptible to cracking. The loop contacts of the present invention are made from solid metal wires or ribbons. These solid metal wires or ribbons are stronger than the solder or stud bumps, thereby the loop contacts do not crack as easily after board mounting as with devices having stud bumps.

### BRIEF DESCRIPTION OF THE DRAWINGS

FIG. 1 is a plan view of a semiconductor device in accordance with a first embodiment of the present invention;

FIG. 1a is a sectional view taken along line 1a-1a in FIG. 1;

FIG. 1b is a sectional view taken along line 1b-1b in FIG. 1;

FIG. 2 is a plan view of a semiconductor device in accordance with a second embodiment of the present invention;

FIG. 2a is sectional view taken along line 2a-2a in FIG. 2;

FIG. 3 is a plan view of a semiconductor device in accordance with a third embodiment of the present invention;

FIG. 3a is a sectional view taken along line 3a-3a in FIG. 3; and

FIG. 3b is a sectional view taken along line 3b-3b in FIG. 3.

Corresponding reference characters indicate corresponding parts throughout the several views. The examples set out herein illustrate several embodiments of the invention but should not be construed as limiting the scope of the invention in any manner.

### DETAILED DESCRIPTION

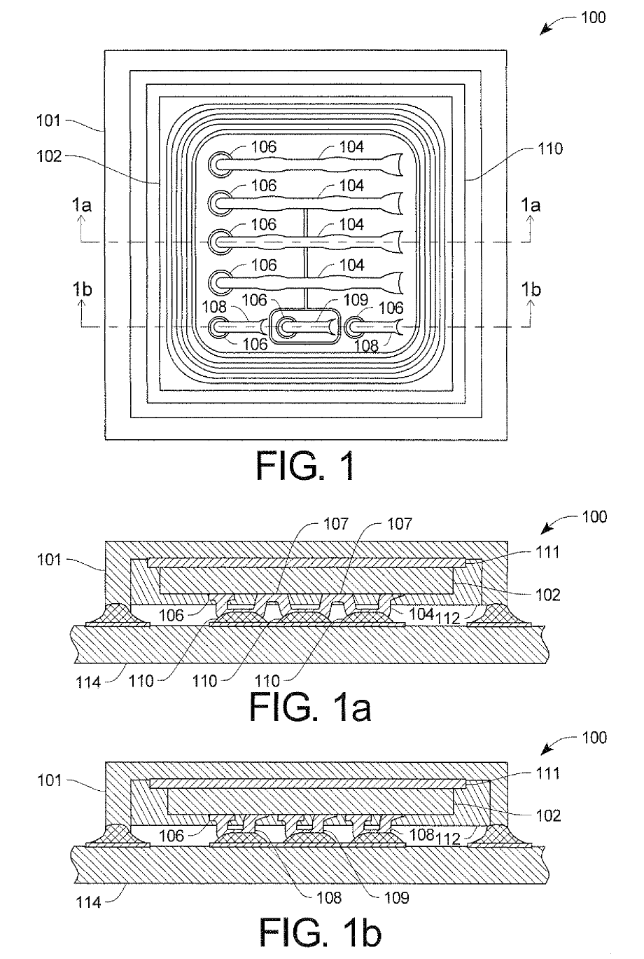

FIG. 1 illustrates a first embodiment of the present invention in a semiconductor device 100. The device is a packaged semiconductor 100 having loop contacts 104, 108, 109 made of solderable material bonded to the semiconductor die 102. The semiconductor die 102 is a flip chip having gate, source, and drain regions. The source and gate regions are on the top surface of the semiconductor die 102 with the drain region on the bottom surface. The drain region is attached to a die attach pad 101, making a drain connection with the die attach pad. The source and gate regions of the semiconductor die 102 have loop contacts 104, 108, 109. The device 100 shows both multi loop contacts 104 and single loop post contacts 108, 109. The loop contacts are bonded to the semiconductor die 102 using thermosonic ball bonding methods which are explained further below.

Referring to FIGS. 1 and 1a, the device 100 may have multi loop post contacts made from wire in which a single thread of wire is used to male multiple loops on the semiconductor die 102 for creating solder surfaces. In this embodiment, wire is used to make the multi loop contacts 104 and the single loop contacts 108, 109.

The thermosonic ball bonding process creates a spherical shape at the bonding point thereby creating a ball bond 106. Generally, the wire used for the loop contacts is passed through a hollow capillary. An electronic-flame-off system melts the wire beneath the capillary through which the wire passes. This wire is, as stated above, solidifies into a spherical shape to create the ball bond. The melted wire beneath the capillary is pressed into the material with which the bond is being formed with sufficient force to allow for plastic deformation and atomic interdiffusion. The thermosonic ball bonding process uses temperatures ranging between 100° C. to 280° C., and the heat is provided in a pedestal upon which the device with which the wire is to be bonded sits. When using copper wires the bonding process must be performed in an inert-atmosphere to prevent oxidation, since copper readily oxidizes.

After the first bond is formed the capillary is raised releasing wire through the capillary until the wire is again pressed into the second bonding site and heated, along with the application of ultrasonic energy, to cause plastic deformation and atomic interdiffusion. The second bond is in a wedge shape due to the shape of the capillary device through which the wire is fed. This process may be followed to create as many loop contacts as needed. At the last loop contact, a wire clamp is closed and the capillary breaks the wire just above the last wedge bond.

Referring to 1 and 1a, the semiconductor device 100 has three loop contacts 104 with a ball bond 106 and two wedge bonds 107 between the three loop contacts 104. These multiple loop contacts 104 are formed on the source region of the semiconductor die 102, thereby creating source contacts. An application board 114 is attached by solder 110 to the loop contacts 104, 108, 109, and the semiconductor die 102 is die bonded to the die attach pad 101 by die attach material 111. Further this first embodiment may optionally be packaged by encapsulating the device prior to attaching the application board 114 with encapsulating materials 112.

With respect to FIGS. 1 and 1b, FIG. 1b shows a sectional view of the single loop contacts 108, 109 of the device 100 of FIG. 1. The single loop contacts 108 are formed on the source region of the semiconductor die 102 and are therefore source loop contacts 108. The single loop contact 109 in the center in FIGS. 1 and 1b is a gate loop contact 109 formed on the gate region of the die 102.

The loop contacts 104, 108, 109 may be made from gold or copper wire or other suitable metal. Further, the wire can be coated by nickel, palladium, copper, platinum, or other solderable metals.

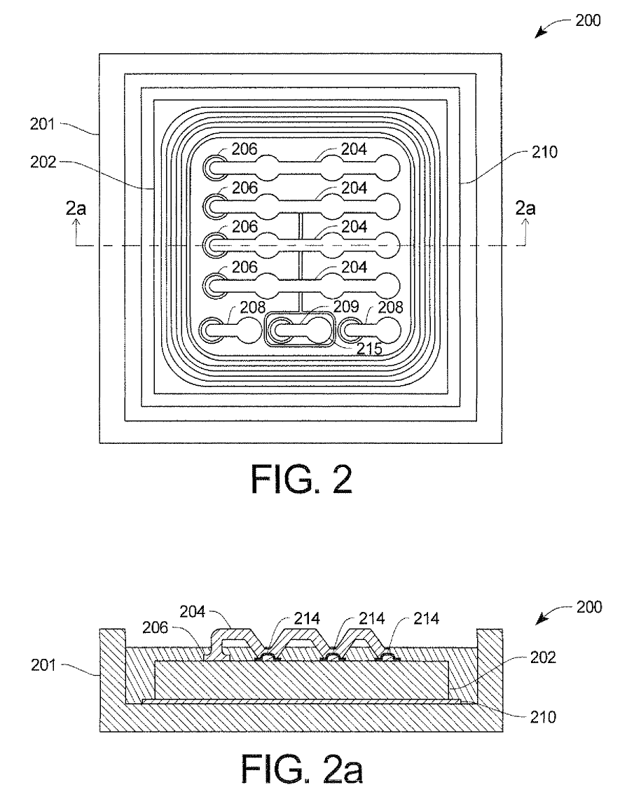

Turning to a second embodiment shown in FIGS. 2 and 2a, the semiconductor device 200 of FIG. 2 has solderable loop contacts 204, 208, 209 formed on stud bumps 214, 215 on the semiconductor die 202. The semiconductor die 202 has a drain region on the bottom surface of the die 202 with the top surface contains the source and gate regions. Referring to FIG. 2a, the drain region of the semiconductor die 202 is attached to the die attach pad 201, and the loop contacts 204, 208 on the stud bumps 214, 215. The loop contacts 204, 208, 209 are formed by thermosonic ball bonding similar to the process as described above, however, the semiconductor die 202 has stud bumps 214, 215. The stud bumps are used to protect the semiconductor die 202 during the bonding process. As mentioned above, the thermosonic bonding process requires heat to cause plastic deformation and atomic intermetallization of the wire and the material to which the wire is being bonded. Applying heat directly to the semiconductor die could damage the die. As such, bonding the wire to stud bumps 214, 215 on the die 202 can prevent or minimize damage to the die 202.

FIG. 2 shows the semiconductor device 200 with both multi loop contacts 204 and single loop contacts 208, 209 by bonding the wire using thermosonic ball bonding technique to form the loop contacts, 204, 208, 209. The multi loop contacts 204 and single loop contacts 208 arc formed on the source bumps 214 of the die 202, and the middle single loop contact 209 is formed on the gate bumps 215 of the semiconductor die 202. The wire used to make the loop post contacts 204, 208, 209 may be copper, gold, or other suitable metal wires, and may further be coated with a solderable metal such as copper, nickel, palladium, or platinum.

FIG. 2a shows a sectional view of the multi loop contacts 204 with the source stud bumps 214 outlined. The multi loop contacts 204, however, have one bond 206 directly to the semiconductor die 202. The initial ball bond 206 as described in thermosonic ball bonding process is made directly to the semiconductor die 202. Also, the semiconductor device 202 may also be packaged leaving the loop contacts 204, 208, 209 exposed through the encapsulating material. The exposed loop contacts 204, 208, 209 are used as gate and source connections.

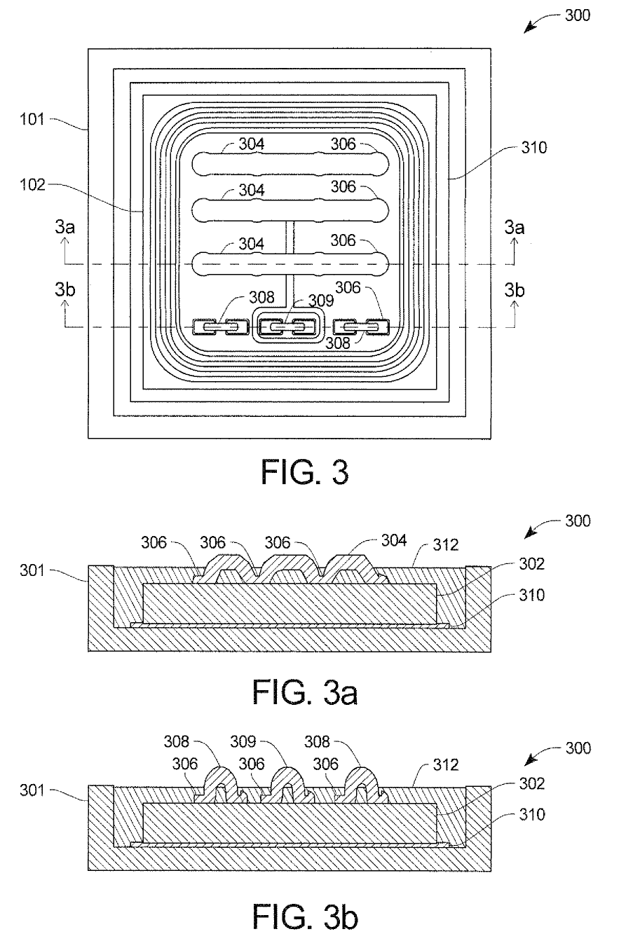

Referring to FIGS. 3, 3a, and 3b, the third embodiment of this invention shows a semiconductor device 300 with loop contacts 304, 308, 309 made from a ribbon. Wire, however, may be used in place of a ribbon. Further the ribbons are bonded directly to the semiconductor die 302 using an ultrasonic wedge bonding technique. The semiconductor die 302 has a drain region on one surface the die 302 with the opposing surface housing the source and gate region. The drain region of the die 302 is attached to the die attach pad 301 by solder 310. The device 300 has both single loop contacts 308, 309 and multi loop contacts 304 boned directly to the die 302.

FIG. 3a shows a sectional view of the multi loop contacts of the device 300 in FIG. 3. The multi loop contacts 304 are bonded directly to the die 302 using an ultrasonic bonding method. Ultrasonic bonding produces wedge bonds 306 by feeding a ribbon or wire at an angle into the bonding tool. The wire is held to a semiconductor die 302 and ultrasonic energy is applied to create the bond 306 between the wire and the die 302. This process does not require the high temperatures of the thermosonic ball bonding process; ultrasonic bonding requires about 25° C. The process is repeated to create the desirable numbers of loop contacts. The wire is cut by either using a wire cutter installed together with bonding tool or by clamps by keeping the clamps in one position and raising the bonding tool to tear the wire as it is raised.

FIG. 3a, this perspective shows the multi loop contacts 304 bonded to the semiconductor die 302 with the device 300 encapsulated leaving the loop contacts 304 exposed through the encapsulating material 312.

FIG. 3b shows a sectional view of the single loop contacts 308, 309 bonded to the semiconductor die 302 on the source and gate regions thereby creating single source loop contacts 308 and a single gate loop contact 309. Again the device 300 is packaged with encapsulating material 312 covering the semiconductor die 302 leaving portions of the loop contacts 308, 309 exposed, for soldering to another surface. FIG. 3 shows a ribbon loop contact 304, 308, 309, but as mentioned above, a wire may be substituted for the ribbon in this embodiment. The wire or ribbon may be of a suitable solderable metal such as aluminum, copper, or gold, and may further coated by copper, nickel, palladium, or platinum.

The method of manufacturing these devices form a considerable advantage over previous semiconductor device having bumps or balls and semiconductor devices having a solderable metal coating. With respect to the first embodiments, the method of manufacturing requires attaching the drain region of the semiconductor die to a die attach pad. Thereafter the wire is bonded to the source region of the semiconductor die using a thermosonic ball bonding technique as previously described. The wire bonding process can be used to make either single loop or multi loop contacts on the die. As shown in the first embodiment there are both single and multi loop contacts on the semiconductor die. The materials for the loop post contacts may be a solderable metal that is optionally coated with another solderable metal. For example, the wire may be either copper or gold and may be coated with either copper, nickel, palladium, or platinum. After the loop contacts are bonded to the die, the die may be optionally covered with an encapsulating material, leaving the loop contacts exposed through the encapsulating material. Then the loop contacts are attached to an application board by solder.

The method of manufacturing the device of the second embodiment requires use of a semiconductor die having stud bumps or balls upon which the stitch or wedge bonds are formed after the initial ball bond is formed on the semiconductor die. The drain region of the die is attached to the die attach pad. Then by using the thermosonic bonding technique the wire is bonded in a ball shape on the semiconductor die with the other bonds formed on the stud bumps on the semiconductor die. The wire used in this embodiment are again solderable metal wires such as copper or gold and may be coated with a solderable metal such as copper, nickel, palladium, or platinum. Thereafter, the semiconductor device may be optionally encapsulated using a suitable encapsulating material leaving the loop contacts exposed through the material.

With respect to the third embodiment, the semiconductor device has solderable loop contacts, as in the first embodiment, bonded to the semiconductor die. However, the die is first attached to the die attach pad. Then, the loop contacts are formed on the die using ultrasonic bonding techniques. The loop contacts in this embodiment may be made by either a wire or ribbon made from a solderable metal such as copper, gold, or aluminum. Also the wire or ribbon may be coated with other solderable metals such as copper, nickel, palladium, or platinum. The ribbon or wire is bonded directly to the die by using ultrasonic energy and makes a wedge bond. The loop contacts may be made in either a single loop, multi loop, or both on the die. The third embodiment has both multi and single loop contacts on the source region of the die and a single gate loop contact. The device may optionally may be covered with encapsulating material leaving the loop contacts exposed through the encapsulating material.

While the invention has been described with the embodiment of a MOSFET device, it is understood by those skilled in the art, the invention may be used with other semiconductor dies, such as diodes, IGBTs, thyristors, and bipolar junction transistors.

While the invention has been described with reference to preferred embodiments, it will be understood by those skilled in the art that various changes may be made and equivalents may be substituted for elements thereof to adapt to particular situations without departing from the scope of the invention. Therefore, it is intended that the invention not be limited to the particular embodiments disclosed as the best mode contemplated for carrying out this invention, but that the invention will include all embodiments falling within the scope and spirit of the appended claims.

1. A semiconductor device comprising:
a. a semiconductor die comprising a first surface having one or more terminals and a second surface having at least one terminal;
b. a die attach pad with leads;
c. at least one loop solderable contact to one of the terminals on the first surface of the semiconductor die; and

2. The device of claim 1, wherein the solderable loop contacts are formed from a metal wire.

3. The device of claim 2, wherein the wire is a metal selected from the group consisting of copper, aluminum, and gold.

4. The device of claim 3, wherein the wire is coated with a solderable material.

5. The device of claim 4, wherein the solderable material is a metal selected from the group consisting of copper, nickel, palladium, and platinum.

6. The device of claim 5, further comprising an application board.

7. The device of claim 3, wherein the solderable loop contacts are formed by thermosonic ball bonding.

8. The device of claim 3, wherein the solderable loop contacts are formed by ultrasonic wedge bonding.

9. The device of claim 4, wherein the solderable loop contacts are formed by thermosonic ball bonding.

10. The device of claim 4, wherein the solderable loop contacts are formed by ultrasonic wedge bonding.

11. The device of claim 1, wherein the solderable loop contacts are formed from a ribbon.

12. The device of claim 11, wherein the ribbon is a metal selected from the group consisting of copper, aluminum, and gold.

13. The device of claim 12, wherein the ribbon is coated with a solderable material.

14. The device of claim 13, wherein the solderable material is a metal selected from the group consisting of copper, nickel, palladium, and platinum.

15. The device of claim 14, wherein the solderable loop contacts are formed by ultrasonic bonding.

16. The device of claim 1, further comprising packaging material.

17. The device of claim 1, wherein the semiconductor die is one of a group consisting of diodes, MOSFETs, IGBTs, thyristors, and bipolar junction transistors.

18. A method of manufacturing a semiconductor device having loop post contacts comprising:
a. providing a semiconductor die, a die attach pad with leads, and a solderable loop contact material in the form of a wire or ribbon;
b. attaching the die to the die attach pad;
c. bonding the loop post contact material in a loop shape to the die.

19. The method of claim 18, wherein the bonding step is thermosonic bonding, wherein the loop contacts are a solderable loop contact material is a metal wire selected from the group of copper, gold, and aluminum.

20. The method of claim 19, wherein the wire is coated with a solderable metal selected from the group consisting of copper, nickel, palladium, and platinum.

21. The method of claim 20, wherein the thermosonic bonding consists of a bond stitch over ball under multi stitch.

22. The method of claim 18, wherein the bonding step is ultrasonic bonding, wherein the loop post contacts are a metal wire or ribbon selected from the group consisting of aluminum, copper, and gold.

23. The method of claim 22, wherein the wire or ribbon is coated with a solderable metal selected from the group consisting of copper, nickel, palladium, and platinum.

24. The device of claim 18, wherein the semiconductor die is one of a group consisting of diodes, MOSFETs, IGBTs, thyristors, and bipolar junction transistors.
